(19) United States
(12) Patent Application Publication
(10) Pub. No.: US 2024/0142874 A1
(43) Pub. Date: May 2, 2024

(54) NON-CHEMICALLY AMPLIFIED RESIST COMPOSITION AND METHOD OF MANUFACTURING INTEGRATED CIRCUIT DEVICE BY USING THE SAME

(71) Applicant: SAMSUNG ELECTRONICS CO., LTD., Suwon-si (KR)

(72) Inventors: Chawon KOH, Suwon-si (KR); Jiyoung PARK, Suwon-si (KR); Seungyeol BAEK, Suwon-si (KR); Tsunehiro NISHI, Suwon-si (KR); Jinkyu HAN, Suwon-si (KR)

(21) Appl. No.: 18/381,678

(22) Filed: Oct. 19, 2023

(30) Foreign Application Priority Data
Oct. 31, 2022 (KR) 10-2022-0143023

(51) Int. Cl. G03F 7/039; G03F 7/004

(52) U.S. Cl. CPC G03F 7/039; G03F 7/0045

(57) ABSTRACT

A non-chemically amplified resist composition includes a photo-decomposable organic resin including a C—O bond in a main chain thereof; an acidic chain scission enhancer; and a solvent.

### CROSS-REFERENCE TO RELATED APPLICATION

This application is based on and claims priority under 35 U.S.C. § 119 to Korean Patent Application No. 10-2022-0143023, filed on Oct. 31, 2022, in the Korean Intellectual Property Office, the disclosure of which is incorporated by reference herein in its entirety.

### BACKGROUND

### 1. Field

Embodiments relate to a non-chemically amplified resist composition and a method of manufacturing an integrated circuit device by using the non-chemically amplified resist composition.

### 2. Description of the Related Art

Due to the advancement of electronics technology, semiconductor devices have been rapidly down-scaled. Therefore, photolithography processes having good effects in implementing fine patterns are used.

### SUMMARY

The embodiments may be realized by providing a non-chemically amplified resist composition including a photo-decomposable organic resin including a C—O bond in a main chain thereof; an acidic chain scission enhancer; and a solvent.

The embodiments may be realized by providing a non-chemically amplified resist composition including a photo-decomposable organic resin that does not include a protecting group that departs due to exposure to an acid; a chain scission enhancer having an acid dissociation constant (pKa) of about −5 to about 5; and a protic solvent.

The embodiments may be realized by providing a non-chemically amplified resist composition including a photo-decomposable organic resin including a copolymer of a monosaccharide and a monosaccharide derivative; a chain scission enhancer including an acid group and having an acid dissociation constant (pKa) of about 1 to about 5, the acid group including a carboxyl group, a sulfonate group, or a phosphonate group; and a protic solvent.

### BRIEF DESCRIPTION OF THE DRAWINGS

Features will be apparent to those of skill in the art by describing in detail exemplary embodiments with reference to the attached drawings in which:

FIGS. 1 to 5 are cross-sectional views of stages in a method of manufacturing an integrated circuit device, according to some embodiments.

### DETAILED DESCRIPTION

A non-chemically amplified resist composition according to some embodiments may include, e.g., a photo-decomposable organic resin, a chain scission enhancer, and a solvent.

In an implementation, the photo-decomposable organic resin may have some covalent bonds dissociated upon light exposure thereof and thus may be decomposed into molecules having lower molecular weights. In an implementation, some covalent bonds constituting a main chain of the photo-decomposable organic resin may be dissociated due to light exposure thereof. Therefore, the solubility of a resist film in a developer may be increased in a light-exposed region, and a pattern may be formed by selectively removing the light-exposed region. Such a mechanism may be distinguished from a mechanism of a chemically amplified resist (CAR).

In a CAR, a polymer constituting a resist may include a protecting group configured to adjust solubility in a developer. For example, the protecting group may depart from the polymer due or in response to an acid generated by light exposure and may form an additional acid, and the resulting acid may derive the departure of another protecting group again and thus cause a chain of deprotection reactions of the protecting group. Therefore, a functional group exposed by a deprotection reaction may increase the solubility of the polymer in the developer, and thus, the light-exposed region may be selectively removed. In a CAR, an acid may diffuse into a non-light-exposed region due to thermal diffusion in a heat treatment process or the like, and thus, the protecting group in the non-light-exposed region may unintentionally depart from the polymer to generate a pattern defect.

The photo-decomposable organic resin of the non-chemically amplified resist composition according to some embodiments may not include a protecting group in a molecule thereof. In the non-chemically amplified resist composition according to some embodiments, when the non-chemically amplified resist composition is heated during a baking process or the like, development selectivity between the non-light-exposed region and the light-exposed region may be maintained, and line edge roughness (LER) or line width roughness (LWR) of a photoresist pattern may be reduced.

In an implementation, the photo-decomposable organic resin may include a C—O bond, and the C—O bond may be dissociated or otherwise broken by or in response to light exposure. In an implementation, the C—O bond may be a covalent bond having relatively low binding energy (e.g., among covalent bonds constituting the main chain of the photo-decomposable organic resin). In an implementation, the C—O bond in the photo-decomposable organic resin may have a bond dissociation energy of about 75 kcal/mol to about 90 kcal/mol, e.g., about 75 kcal/mol to about 85 kcal/mol, or about 75 kcal/mol to about 83 kcal/mol. Within the aforementioned ranges of bond dissociation energy, the sensitivity of a resist may improve, and the number of photons for pattern formation may be reduced, thereby improving the manufacturing productivity of an integrated circuit device. In an implementation, a resist formed from the non-chemically amplified resist composition may implement a distribution with the same proportions in a fine pattern having a pitch of 40 nm or less even at a relatively low exposure dose (mJ/cm²) of light having the same wavelength.

In an implementation, the photo-decomposable organic resin may include a nucleic acid. In an implementation, the photo-decomposable organic resin may include a copolymer of nucleotides. In an implementation, in each of the nucleotides, a sugar may include ribose or deoxyribose, a base may include guanine, adenine, thymine, cytosine, or uracil, and a phosphate may include a monophosphate, a diphosphate, or a triphosphate. In an implementation, the nucleic acid may include deoxyribonucleic acid (DNA). In an implementation, upon light exposure, a C—O bond of carbon 3 or a C—O bond of carbon 5 in deoxyribose of the DNA may be dissociated. In an implementation, the nucleic acid may include ribonucleic acid (RNA). In an implementation, upon light exposure, a C—O bond of carbon 3 or a C—O bond of carbon 5 in ribose of the RNA may be dissociated. A base sequence of each of the DNA and the RNA may vary. In an implementation, the DNA may include a complementary combination of guanine, adenine, thymine, and cytosine, and the RNA may include a complementary combination of guanine, adenine, uracil, and cytosine. As used herein, the term “or” is not an exclusive term, e.g., “A or B” would include A, B, or A and B.

In an implementation, the photo-decomposable organic resin may include a polysaccharide or a polysaccharide derivative. In an implementation, the photo-decomposable organic resin may include a copolymer of a monosaccharide or a monosaccharide derivative. In an implementation, the monosaccharide may include glucose, fructose, galactose, mannose, or isomers thereof. In an implementation, the monosaccharide derivative may include a compound in which a hydroxyl group of the monosaccharide is substituted with a hydrogen atom or a C1 to C30 aliphatic hydrocarbon group. In an implementation, the C1 to C30 aliphatic hydrocarbon group may include a linear, branched, or cyclic hydrocarbon group.

In an implementation, the C1 to C30 aliphatic hydrocarbon group may include a C1 to C30 alkyl group, a C3 to C30 cycloalkyl group, or a C1 to C30 heterocycloalkyl group. In an implementation, the C1 to C30 heterocycloalkyl group may include, as a heteroatom, an oxygen atom, a nitrogen atom, a sulfur atom, or a phosphorus atom

In an implementation, the C1 to C30 aliphatic hydrocarbon group may include a substitutable C1 to C30 alkyl group, a substitutable C3 to C30 cycloalkyl group, or a substitutable C3 to C30 heterocycloalkyl group. As used herein the term “substitutable” means that at least one of hydrogen atoms bonded to carbon atoms may be substituted with a halogen atom, a heteroatom, a hydroxyl group, a C1 to C10 alkyl group, a C1 to C10 ester group, a C1 to C10 alkoxy group, a carboxyl group, a C1 to C10 carbonyl group, an amino group, a C1 to C10 amide group, a phosphoric acid group, a nitro group, or a thiol group. In an implementation, the heteroatom may include an oxygen atom, a nitrogen atom, a sulfur atom, or a phosphorus atom.

In an implementation, upon light exposure, a C—O bond of a glycosidic bond constituting a main chain of the polysaccharide or the polysaccharide derivative may be dissociated. In an implementation, the photo-decomposable organic resin may be decomposed into a polysaccharide, a polysaccharide derivative, a monosaccharide, or a monosaccharide derivative, which are of smaller units, and thus may be dissolved by a developer in a development process.

In an implementation, the photo-decomposable organic resin may have a number average molecular weight (Mn) of about 5,000 g/mol to about 50,000 g/mol. According to some embodiments, the photo-decomposable organic resin may have a polydispersity index (weight average molecular weight (Mw)/number average molecular weight (Mn)) of about 1.3 to about 5. Herein, each of the weight average molecular weight (Mw) and the number average molecular weight (Mn) refers to a value according to polystyrene conversion. In an implementation, in the light-exposed region, the photo-decomposable organic resin may be decomposed into small molecules having number average molecular weights (Mn) of about 50 g/mol to about 1,000 g/mol.

In an implementation, the photo-decomposable organic resin may be present in an amount of about 3% by weight (wt %) to about 30 wt %, based on a total weight of the non-chemically amplified resist composition. Within the aforementioned range of the amount of the photo-decomposable organic resin, a high-resolution pattern may be stably implemented even at a low exposure dose.

In an implementation, the chain scission enhancer may function as an acid catalyst reducing bond dissociation energy of the C—O bond of the photo-decomposable organic resin. In an implementation, a proton provided by the chain scission enhancer may attract an electron of an oxygen atom constituting the C—O bond of the photo-decomposable organic resin, and thus, the bond dissociation energy of the C—O bond may be reduced. The non-chemically amplified resist composition according to some embodiments may include the chain scission enhancer and thus may implement a high-resolution pattern at a relatively low exposure dose.

In an implementation, the chain scission enhancer may include an acid having an acid dissociation constant (pKa) of, e.g., about −10 to about 5. Herein, the pKa may refer to an acid dissociation constant in water. In an implementation, the chain scission enhancer may have a pKa of about −5 to about 5, e.g., about 1 to about 5. If the pKa were to be too low, the covalent bonds constituting the photo-decomposable organic resin in the non-light-exposed region could be dissociated, and the selectivity of development could deteriorate. If the pKa were to be too high, the photo-decomposable organic resin in the light-exposed region may not be decomposed into molecules having sufficiently low molecular weights to be dissolved by a developer.

In an implementation, the chain scission enhancer may include an acid group, e.g., a carboxyl group, a sulfonate group, or a phosphonate group.

In an implementation, the chain scission enhancer having a pKa of about 1 to about 5 may include, e.g., acetic acid, citric acid, formic acid, gluconic acid, lactic acid, oxalic acid, tartaric acid, fluoroacetic acid, trifluoroacetic acid, chloroacetic acid, dichloroacetic acid, trichloroacetic acid, or ascorbic acid.

In an implementation, the chain scission enhancer having a pKa of about −5 to about 1 may include, e.g., methanesulfonic acid, ethanesulfonic acid, benzenesulfonic acid, p-toluenesulfonic acid, polystyrene sulfonic acid, sulfuric acid, nitric acid, phosphoric acid, or chromic acid.

In an implementation, the chain scission enhancer may be present in an amount of about 0.01 wt % to about 20 wt %, based on the total weight of the non-chemically amplified resist composition. If the amount of the chain scission enhancer were to be too low, dissolution selectivity in a developer between the light-exposed region and the non-light-exposed region could be insufficiently implemented. If the amount of the chain scission enhancer were to be too high, the capability of forming a photoresist film by using the non-chemically amplified resist composition could deteriorate.

In an implementation, the solvent may include a protic solvent. Protons of the protic solvent may help reduce the bond dissociation energy of the C—O bond of the photo-decomposable organic resin. In an implementation, the dissociation of the C—O bond of the photo-decomposable organic resin may be derived by the protons provided by the protic solvent.

In an implementation, the protic solvent may include, e.g., an alcohol solvent, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, n-octanol, 2-ethylhexanol, sec-octanol, n-nonyl alcohol, n-decanol, sec-undecyl alcohol, trimethylnonyl alcohol, sec-tetradecyl alcohol, sec-heptadecyl alcohol, cyclohexanol, methylcyclohexanol, benzyl alcohol, ethylene glycol, 1,2-propylene glycol, 1,3-butylene glycol, diethylene glycol, dipropylene glycol, triethylene glycol, or tripropylene glycol; an ether solvent, such as ethylene glycol methyl ether, ethylene glycol ethyl ether, ethylene glycol monophenyl ether, diethylene glycol monomethyl ether, diethylene glycol monoethyl ether, diethylene glycol mono-n-butyl ether, diethylene glycol mono-n-hexyl ether, ethoxytriglycol, tetraethylene glycol mono-n-butyl ether, propylene glycol monomethyl ether, propylene glycol propyl ether, dipropylene glycol monomethyl ether, dipropylene glycol monoethyl ether, or tripropylene glycol monomethyl ether; an ester solvent, such as methyl lactate, ethyl lactate, n-butyl lactate, or n-amyl lactate; water; or a combination thereof.

In an implementation, the solvent may further include an aprotic solvent. In an implementation, a mixture of the protic solvent and the aprotic solvent may be used as the solvent. In an implementation, the aprotic solvent may include, e.g., an ether solvent, such as diethyl ether, methyl ethyl ether, methyl-n-di-n-propyl ether, di-iso-propyl ether, tetrahydrofuran, methyltetrahydrofuran, dioxane, dimethyldioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ethyl ether, diethylene glycol methyl mono-n-propyl ether, diethylene glycol methyl mono-n-butyl ether, diethylene glycol di-n-propyl ether, diethylene glycol di-n-butyl ether, diethylene glycol methyl mono-n-hexyl ether, triethylene glycol dimethyl ether, triethylene glycol diethyl ether, triethylene glycol methyl ethyl ether, triethylene glycol methyl mono-n-butyl ether, triethylene glycol di-n-butyl ether, triethylene glycol methyl mono-n-hexyl ether, tetraethylene glycol dimethyl ether, tetraethylene glycol diethyl ether, tetraethylene glycol methyl ethyl ether, tetraethylene glycol methyl mono-n-butyl ether, diethylene glycol di-n-butyl ether, tetraethylene glycol methyl mono-n-hexyl ether, tetraethylene glycol di-n-butyl ether, propylene glycol dimethyl ether, propylene glycol diethyl ether, propylene glycol di-n-propyl ether, propylene glycol dibutyl ether, dipropylene glycol dimethyl ether, dipropylene glycol diethyl ether, dipropylene glycol methyl ethyl ether, dipropylene glycol methyl mono-n-butyl ether, dipropylene glycol di-n-propyl ether, dipropylene glycol di-n-butyl ether, dipropylene glycol methyl mono-n-hexyl ether, tripropylene glycol dimethyl ether, tripropylene glycol diethyl ether, tripropylene glycol methyl ethyl ether, tripropylene glycol methyl mono-n-butyl ether, tripropylene glycol di-n-butyl ether, tripropylene glycol methyl mono-n-hexyl ether, tetrapropylene glycol dimethyl ether, tetrapropylene glycol diethyl ether, tetradipropylene glycol methyl ethyl ether, tetrapropylene glycol methyl mono-n-butyl ether, tetrapropylene glycol di-n-butyl ether, tetrapropylene glycol methyl mono-n-hexyl ether, or tetrapropylene glycol di-n-butyl ether; an ester solvent, such as methyl acetate, ethyl acetate, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, nonyl acetate, methyl acetoacetate, ethyl acetoacetate, diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, or di-n-butyl oxalate; an ether acetate solvent, such as ethylene glycol methyl ether propionate, ethylene glycol ethyl ether propionate, ethylene glycol methyl ether acetate, ethylene glycol ethyl ether acetate, diethylene glycol methyl ether acetate, diethylene glycol ethyl ether acetate, diethylene glycol n-butyl ether acetate, propylene glycol methyl ether acetate, propylene glycol ethyl ether acetate, propylene glycol propyl ether acetate, dipropylene glycol methyl ether acetate, or dipropylene glycol ethyl ether acetate; or a combination thereof.

In an implementation, the solvent may be present in an amount of about 70 wt % to about 90 wt %, based on the total weight of the non-chemically amplified resist composition. In an implementation, the non-chemically amplified resist composition may include the protic solvent in an amount of about 70 wt % to about 90 wt %, based on the total weight of the non-chemically amplified resist composition. If the amount of the protic solvent were to be too low, the photo-decomposable organic resin in the light-exposed region could be insufficiently decomposed. If the amount of the protic solvent were to be too high, it could be difficult to stably form a photoresist pattern.

In an implementation, the non-chemically amplified resist composition may further include, e.g., a photoacid generator (PAG) or a thermal acid generator (TAG).

In an implementation, the PAG may include, e.g., a diazonium salt compound, a phosphonium salt compound, a sulfonium salt compound, an iodonium salt compound, an imide sulfonate compound, an oxime sulfonate compound, a diazodisulfone compound, a disulfone compound, an o-nitrobenzyl sulfonate compound, a triazine compound, or a combination thereof.

In an implementation, the TAG may include, e.g., acidic compounds, such as p-toluenesulfonic acid, trifluoromethanesulfonic acid, pyridinium p-toluenesulfonate, salicylic acid, sulfosalicylic acid, citric acid, benzoic acid, hydroxybenzoic acid, or naphthalene carboxylonic acid; organic sulfonic acid alkyl esters, such as benzoin tosylate or 2-nitrobenzyl tosylate; or a combination thereof. In an implementation, the TAG may include ammonium triflate, ammonium perfluorobutanesulfonate (PFBuS), ammonium [4-adamantanecarboxyl-1,1,2,2-tetrafluorobutane sulfonate] (Ad-TFBS), ammonium Ad-TFBS [4-adamantanecarboxyl-1,1,2,2-tetrafluorobutane sulfonate], ammonium AdOH-TFBS [3-hydroxy-4-adamantanecarboxyl-1,1,2,2-tetrafluorobutane sulfonate], ammonium Ad-DFMS [adamantanyl-methoxycarbonyl)-difluoromethanesulfonate], ammonium AdOH-DFMS [hydroxyadamantanyl-methoxycarbonyl)-difluoromethanesulfonate], ammonium DHC-TFBSS [4-dehydrocholate-1,1,2,2-tetrafluorobutane-sulfonate], ammonium ODOT-DFMS[Hexahydro-4,7-Epoxyisobenzofuran-1(3H)-one,6-(2,2′-difluoro-2-sulfonatoaceticacid ester)], or a combination thereof.

In an implementation, each of the PAG and the TAG may be present in an amount of about 0.01 wt % to about 5 wt % in the non-chemically amplified resist composition.

In an implementation, the photo-decomposable organic resin of the non-chemically amplified resist composition may not include an acid protecting group, even when including the PAG or the TAG, thermal diffusion may be reduced or prevented, and solubility of the non-chemically amplified resist composition in the non-light-exposed region in a developer may not be increased.

In an implementation, the non-chemically amplified resist composition may further include, e.g., a surfactant, a dispersant, a moisture absorber, or a coupling agent.

In an implementation, the surfactant may help improve the coating uniformity and wettability of the non-chemically amplified resist composition. In an implementation, the surfactant may include, e.g., a sulfuric acid ester salt, a sulfonic acid salt, a phosphoric acid ester, soap, an amine salt, a quaternary ammonium salt, polyethylene glycol, an alkylphenol-ethylene oxide adduct, polyhydric alcohol, a nitrogen-containing vinyl polymer, or a combination thereof. In an implementation, the surfactant may include, e.g., an alkylbenzenesulfonic acid salt, an alkylpyridinium salt, polyethylene glycol, or a quaternary ammonium salt. When the non-chemically amplified resist composition includes the surfactant, the surfactant may be present in an amount of about 0.001 wt % to about 3 wt %, based on the total weight of the non-chemically amplified resist composition.

In an implementation, the dispersant may facilitate uniform dispersal of the respective components constituting the non-chemically amplified resist composition in the non-chemically amplified resist composition. In an implementation, the dispersant may include, e.g., an epoxy resin, polyvinyl alcohol, polyvinyl butyral, polyvinylpyrrolidone, glucose, sodium dodecyl sulfate, sodium citrate, oleic acid, linoleic acid, or a combination thereof. When the non-chemically amplified resist composition includes the dispersant, the dispersant may be present in an amount of about 0.001 wt % to about 5 wt %, based on the total weight of the non-chemically amplified resist composition.

In an implementation, the moisture absorber may help prevent adverse effects that could otherwise occur due to moisture in the non-chemically amplified resist composition. In an implementation, the moisture absorber may help prevent a metal in the non-chemically amplified resist composition from being oxidized by moisture. In an implementation, the moisture absorber may include, e.g., polyoxyethylene nonylphenol ether, polyethylene glycol, polypropylene glycol, polyacrylamide, or a combination thereof. When the non-chemically amplified resist composition includes the moisture absorber, the moisture absorber may be present in an amount of about 0.001 wt % to about 10 wt %, based on the total weight of the non-chemically amplified resist composition.

In an implementation, the coupling agent may help improve the adhesion of the non-chemically amplified resist composition with respect to an underlying film when the non-chemically amplified resist composition is coated on the underlying film. In an implementation, the coupling agent may include a silane coupling agent. The silane coupling agent may include, e.g., vinyltrimethoxysilane, vinyltriethoxysilane, vinyltrichlorosilane, vinyltris((3-methoxyethoxy)silane, 3-methacryloxypropyltrimethoxysilane, 3-acryloxypropyltrimethoxysilane, p-styryltrimethoxysilane, 3-methacryloxypropylmethyldimethoxysilane, 3-methacryloxypropylmethyldiethoxysilane, or trimethoxy[3-(phenylamino)propyl]silane. When the non-chemically amplified resist composition includes the coupling agent, the coupling agent may be present in an amount of about 0.001 wt % to about 5 wt %, based on the total weight of the non-chemically amplified resist composition.

The non-chemically amplified resist composition according to an embodiment may have a good effect in forming a pattern having a relatively high aspect ratio. In an implementation, the non-chemically amplified resist composition may be suitably used in a photolithography process for forming a pattern that has a fine width selected from a range of about 5 nm to about 100 nm.

Hereinafter, a method of manufacturing an integrated circuit device by using the non-chemically amplified resist composition according to an embodiment is described by taking a specific example.

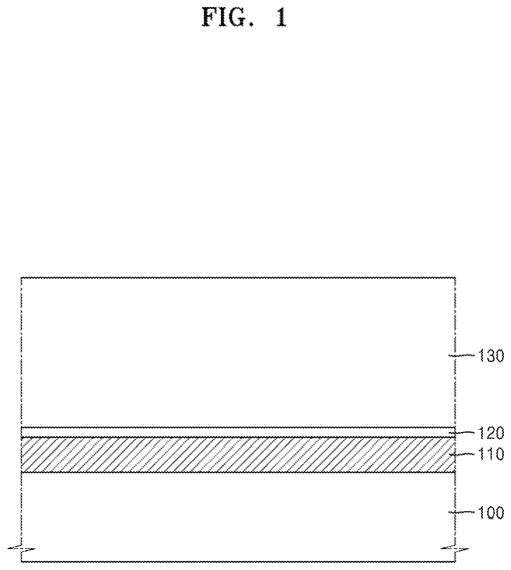

FIGS. 1 to 5 are cross-sectional views of stages in a method of manufacturing an integrated circuit device, according to some embodiments.

Referring to FIG. 1, a feature layer 110 may be formed on a substrate 100, and a photoresist film 130 may be formed on the feature layer 110 by using the non-chemically amplified resist composition according to an embodiment. The photoresist film 130 may include a photo-decomposable organic resin and a chain scission enhancer, which are components of the non-chemically amplified resist composition. A more detailed configuration of the non-chemically amplified resist composition is the same as described above.

The substrate 100 may include a semiconductor substrate. The feature layer 110 may include an insulating film, a conductive film, or a semiconductor film. In an implementation, the feature layer 110 may include, e.g., a metal, an alloy, a metal carbide, a metal nitride, a metal oxynitride, a metal oxycarbide, a semiconductor, polysilicon, oxide, nitride, oxynitride, or a combination thereof.

In an implementation, before the photoresist film 130 is formed on the feature layer 110, a developable bottom anti-reflective coating (DBARC) film 120 may be formed on the feature layer 110. In this case, the photoresist film 130 may be formed on the DBARC film 120. The DBARC film 120 may help control diffuse reflection of light from a light source, which is used in a light exposure process for manufacturing an integrated circuit device, or may absorb light reflected by the feature layer 110 under the DBARC film 120. In an implementation, the DBARC film 120 may include an organic anti-reflective coating (ARC) material for a KrF excimer laser, an ArF excimer laser, or other suitable light source. In an implementation, the DBARC film 120 may include an organic component having a light absorption structure. The light absorption structure may include, e.g., a hydrocarbon compound in which one or more benzene rings are fused. The DBARC film 120 may have, e.g., a thickness of about 0.2 nm to about 10 nm.

In an implementation, to form the photoresist film 130, the non-chemically amplified resist composition according to an embodiment may be coated on the DBARC film 120 and may then be heat-treated. The coating set forth above may be performed by a suitable method, e.g., spin coating, spray coating, or dip coating. A process of heat-treating the non-chemically amplified resist composition may be performed at a temperature of about 80° C. to about 160° C. for about 30 seconds to about 150 seconds. The thickness of the photoresist film 130 may be tens to hundreds of times the thickness of the DBARC film 120. The photoresist film 130 may have a thickness of about 20 nm to about 100 nm.

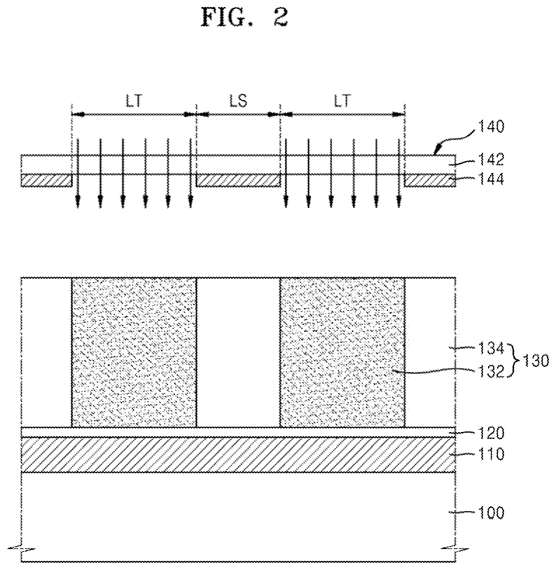

Referring to FIG. 2, a first region 132, which is a portion of the photoresist film 130, may be exposed to light.

As the photoresist film 130 is exposed to light, the photo-decomposable organic resin of the photoresist film 130 in the first region 132 may undergo the dissociation of a C—O bond constituting a main chain thereof and may be decomposed into molecules having lower molecular weights. Therefore, a difference in solubility in a developer between the light-exposed first region 132 and a non-light-exposed second region 134 of the photoresist film 130 may increase.

In an implementation, the photoresist film 130 may be obtained from the non-chemically amplified resist composition according to an embodiment, and the non-chemically amplified resist composition may include a chain scission enhancer having a pKa of about −10 to about 5. In an implementation, the chain scission enhancer may derive or facilitate the dissociation of the C—O bond constituting the main chain of the photo-decomposable organic resin and may help further increase the difference in solubility in the developer between the light-exposed region and the non-light-exposed region.

In an implementation, the photo-decomposable organic resin of the non-chemically amplified resist composition, which is used to form the photoresist film 130, may not include a protecting group that departs due to an acid. If a photo-decomposable organic resin were to include such a protecting group as described above, acids could be additionally generated, because the protecting group bonded to the photo-decomposable organic resin may depart due to the chain scission enhancer, and the acids could diffuse into the non-light-exposed region, during the heat treatment process described above or in a post-bake process described below. In this case, the solubility of the non-light-exposed region in the developer could also increase, and there could be an issue of a reduction in solubility in the developer between the light-exposed region and the non-light-exposed region. According to an embodiment, the photo-decomposable organic resin may not include a protecting group and, in the light-exposed region, may be decomposed into molecules having lower molecular weights, thereby implementing development selectivity between the light-exposed region and the non-light-exposed region. Therefore, in a photoresist pattern obtained as a result, LER or LWR may be reduced to obtain high pattern fidelity.

In an implementation, to expose the first region 132 of the photoresist film 130 to light, a photomask 140, which has a plurality of light shielding areas LS and a plurality of light transmitting areas LT, may be aligned at a certain position above the photoresist film 130, and the first region 132 of the photoresist film 130 may be exposed to light through the plurality of light transmitting areas LT of the photomask 140. To expose the first region 132 of the photoresist film 130 to light, a KrF excimer laser (248 nm), an ArF excimer laser (193 nm), an F₂ excimer laser (157 nm), an EUV laser (13.5 nm), or an E-beam (10 nm or less) may be used. In an implementation, an exposure dose may be about 30 mJ/cm² to about 100 mJ/cm². The photoresist film 130, which is formed from the non-chemically amplified resist composition according to some embodiments, may implement high sensitivity even at an exposure dose of 60 mJ/cm² or less.

In an implementation, the photomask 140 may include a transparent substrate 142 and a plurality of light shielding patterns 144 that is respectively on the transparent substrate 142 at the plurality of light shielding areas LS. The transparent substrate 142 may include quartz. The plurality of light shielding patterns 144 may include chromium (Cr). The plurality of light transmitting areas LT may be defined by the plurality of light shielding patterns 144. In an implementation, to expose the first region 132 of the photoresist film 130 to light, a reflective photomask for EUV light exposure, instead of the photomask 140, may be used.

In an implementation, after the first region 132 of the photoresist film 130 is exposed to light, the photoresist film 130 may undergo post-bake. The post-bake may be performed at a temperature of about 80° C. to about 200° C. for about 30 seconds to about 150 seconds.

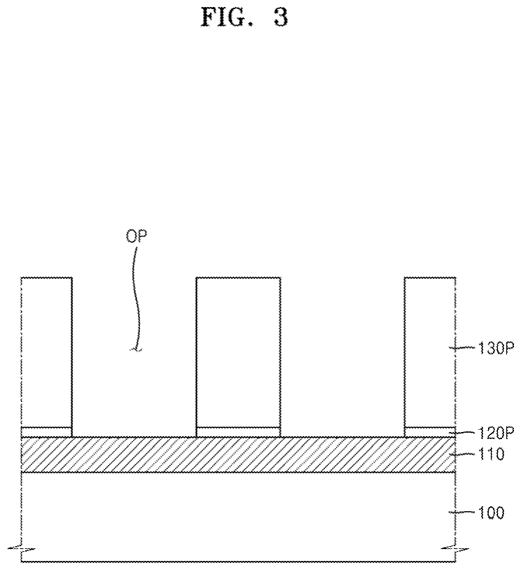

Referring to FIG. 3, a photoresist pattern 130P may be formed by developing the photoresist film 130 exposed to light.

In an implementation, the light-exposed first region 132 of the photoresist film 130 may be removed by developing the light-exposed photoresist film 130 shown in FIG. 2, and the photoresist pattern 130P (including the non-light-exposed second region 134 of the photoresist film 130) may be formed. The photoresist pattern 130P may include a plurality of openings OP. A DBARC pattern 120P may be formed by removing portions of the DBARC film 120, which are exposed by the plurality of openings OP.

In an implementation, the development of the photoresist film 130 may be performed by a positive-tone development (PTD) process. In an implementation, the developer may include a polar organic solvent, a nonpolar organic solvent, or a combination thereof. In an implementation, the type of developer or the combination of developers may be selected according to the photo-decomposable organic resin and the polarity of low-molecular-weight molecules decomposed from the photo-decomposable organic resin.

In an implementation, the solvent of the developer may include, e.g., alcohols, such as methyl alcohol, ethyl alcohol, n-propyl alcohol, isopropyl alcohol, n-butyl alcohol, sec-butyl alcohol, t-butyl alcohol, or isobutyl alcohol; ketones, such as acetone, methyl ethyl ketone, or diacetone alcohol; esters, e.g., ethyl acetate, butyl acetate, ethyl lactate, dipropylene glycol methyl ether acetate (DPMA), diethylene glycol monoethyl ether acetate (EDGAC), propylene glycol methyl ether acetate (PGMEA), 3-methoxy butyl acetate (MBA), or diethylene glycol monobutyl ether acetate (DGMA); polyhydric alcohols, such as ethylene glycol, diethylene glycol, triethylene glycol, propylene glycol, dipropylene glycol, butylene glycol, 1,3-butanediol, 1,4-butanediol, 1,2,4-butanetriol, 1,5-pentanediol, 1,2-hexanediol, 1,2,6-hexanetriol, hexylene glycol, glycerol, glycerol ethoxylate, or trimethylolpropane ethoxylate; lower alkyl ethers, e.g., ethylene glycol monomethyl ether, ethylene glycol monoethyl ether, diethylene glycol methyl ether, diethylene glycol ethyl ether, triethylene glycol monomethyl ether, or triethylene glycol monoethyl ether; nitrogen-containing compounds, e.g., 2-pyrrolidone or N-methyl-2-pyrrolidone; sulfur-containing compounds, e.g., dimethyl sulfoxide, tetramethylene sulfone, or thioglycol; or a combination thereof.

In the photoresist film 130 shown in FIG. 2, the C—O bond constituting the main chain of the photo-decomposable organic resin may be dissociated in the light-exposed first region 132 due to the chain scission enhancer, and a difference in solubility in the developer between the light-exposed first region 132 and the non-light-exposed second region 134 may increase. Accordingly, as the first region 132 is removed by developing the photoresist film 130, the second region 134 may remain as it is without being removed. Therefore, a distribution may be uniformly controlled in a fine pattern having a pitch of 40 nm or less, and a high-resolution pattern having reduced LER and LWR may be implemented.

As such, the profile of the photoresist pattern 130P may improve, and a critical dimension of an intended processing region in the feature layer 110 may be precisely controlled when the feature layer 110 is processed by using the photoresist pattern 130P.

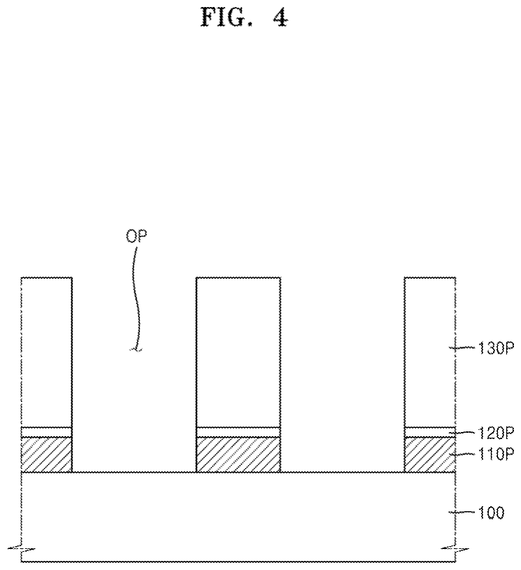

Referring to FIG. 4, in a resulting product of FIG. 3, the feature layer 110 may be processed by using the photoresist pattern 130P.

In an implementation, to process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, or a process of modifying portions of the feature layer 110 through the openings OP, may be performed. FIG. 4 illustrates that a feature pattern 110P is formed by etching the feature layer 110 exposed by the openings OP, as an example process of processing the feature layer 110.

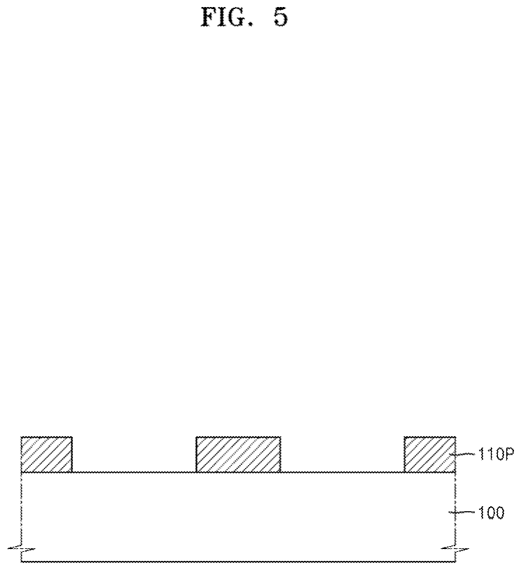

Referring to FIG. 5, the photoresist pattern 130P and the DBARC pattern 120P, which remain on the feature pattern 110P, may be removed from a resulting product of FIG. 4. To remove the photoresist pattern 130P and the DBARC pattern 120P, ashing and strip processes may be used.

According to the method of manufacturing an integrated circuit device, which is described with reference to FIGS. 1 to 5, a precise difference in solubility in a developer between a light-exposed region and a non-light-exposed region may be implemented in the photoresist film 130 obtained from the non-chemically amplified resist composition according to an embodiment, even at a relatively lower exposure dose. Therefore, the productivity of a manufacturing process of an integrated circuit device may improve, and when a subsequent process is performed on the feature layer 110 by using the photoresist pattern 130P, critical dimensions of processing regions or patterns intended to be formed in or on the feature layer 110 may be precisely controlled, thereby improving the dimensional precision thereof.

By way of summation and review, chemically amplified resists (CARs) may use a mechanism in which the solubility of polymer resins in developers varies due to chain reactions caused by photons. CARs may have an issue of a deterioration in pattern quality because photoacid generators causing chain reactions thermally diffuse in processes such as bake or the like.

One or more embodiments may provide a non-chemically amplified resist composition capable of implementing excellent sensitivity and resolution in a photolithography process for manufacturing an integrated circuit device.

One or more embodiments may provide a method of manufacturing an integrated circuit device having a high-resolution fine pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A non-chemically amplified resist composition, comprising:
a photo-decomposable organic resin including a C—O bond in a main chain thereof;
an acidic chain scission enhancer; and
a solvent.

2. The non-chemically amplified resist composition as claimed in claim 1, wherein the acidic chain scission enhancer has an acid dissociation constant (pKa) of about −10 to about 5.

3. The non-chemically amplified resist composition as claimed in claim 1, wherein the acidic chain scission enhancer includes a carboxyl group, a sulfonate group, or a phosphonate group.

4. The non-chemically amplified resist composition as claimed in claim 1, wherein the photo-decomposable organic resin includes a nucleic acid.

5. The non-chemically amplified resist composition as claimed in claim 1, wherein the photo-decomposable organic resin includes a polysaccharide.

6. The non-chemically amplified resist composition as claimed in claim 1, wherein the solvent includes a protic solvent.

7. The non-chemically amplified resist composition as claimed in claim 1, wherein the photo-decomposable organic resin does not include a protecting group that departs due to exposure to an acid.

8. The non-chemically amplified resist composition as claimed in claim 1, further comprising a surfactant, a dispersant, a moisture absorber, or a coupling agent.

9. The non-chemically amplified resist composition as claimed in claim 1, wherein the non-chemically amplified resist composition includes:
about 3 wt % to about 30 wt % of the photo-decomposable organic resin;
about 0.01 wt % to about 20 wt % of the acidic chain scission enhancer; and
about 70 wt % to about 90 wt % of the solvent, all wt % being based on a total weight of the non-chemically amplified resist composition.

10. A non-chemically amplified resist composition, comprising:
a photo-decomposable organic resin that does not include a protecting group that departs due to exposure to an acid;
a chain scission enhancer having an acid dissociation constant (pKa) of about −5 to about 5; and
a protic solvent.

11. The non-chemically amplified resist composition as claimed in claim 10, wherein the chain scission enhancer includes a photoacid generator or a thermal acid generator.

12. The non-chemically amplified resist composition as claimed in claim 10, wherein the chain scission enhancer includes acetic acid, citric acid, formic acid, gluconic acid, lactic acid, oxalic acid, tartaric acid, fluoroacetic acid, trifluoroacetic acid, chloroacetic acid, dichloroacetic acid, trichloroacetic acid, or ascorbic acid.

13. The non-chemically amplified resist composition as claimed in claim 10, wherein the chain scission enhancer includes methanesulfonic acid, ethanesulfonic acid, benzenesulfonic acid, p-toluenesulfonic acid, or polystyrene sulfonic acid.

14. The non-chemically amplified resist composition as claimed in claim 10, wherein the chain scission enhancer includes sulfuric acid, nitric acid, phosphoric acid, or chromic acid.

15. The non-chemically amplified resist composition as claimed in claim 10, wherein the photo-decomposable organic resin includes deoxyribonucleic acid (DNA) or ribonucleic acid (RNA).

16. The non-chemically amplified resist composition as claimed in claim 10, further comprising a surfactant, a dispersant, a moisture absorber, or a coupling agent.

17. A non-chemically amplified resist composition, comprising:
a photo-decomposable organic resin including a copolymer of a monosaccharide and a monosaccharide derivative;
a chain scission enhancer including an acid group and having an acid dissociation constant (pKa) of about 1 to about 5, the acid group including a carboxyl group, a sulfonate group, or a phosphonate group; and
a protic solvent.

18. The non-chemically amplified resist composition as claimed in claim 17, wherein the photo-decomposable organic resin does not include a protecting group that departs due to exposure to an acid.

19. The non-chemically amplified resist composition as claimed in claim 17, wherein:
the photo-decomposable organic resin includes a C—O bond in a main chain thereof, and
the C—O bond has a bond dissociation energy of about 75 kcal/mol to about 85 kcal/mol.

20. The non-chemically amplified resist composition as claimed in claim 17, wherein the non-chemically amplified resist composition includes:
about 3 wt % to about 30 wt % of the photo-decomposable organic resin;
about 0.01 wt % to about 20 wt % of the chain scission enhancer; and
about 70 wt % to about 90 wt % of the protic solvent, all wt % being based on a total weight of the non-chemically amplified resist composition.
